(19) United States
(12) Patent Application Publication
(10) Pub. No.: US 2023/0260814 A1
(43) Pub. Date: Aug. 17, 2023

(54) EXCLUSION RING FOR SUBSTRATE PROCESSING

(71) Applicant: Lam Research Corporation, Fremont, CA (US)

(72) Inventors: Vinayakaraddy Gulabal, Yadgir (IN); Ravi Vellanki, San Jose, CA (US); Eashan Raju Dhawade, Nagpur (IN); Alok Mahadeva, Bangalore (IN); Erica Maxine Chen, Newark, CA (US); Xiaolan Ba, Fremont, CA (US)

(21) Appl. No.: 18/013,749

(22) PCT Filed: Jul. 13, 2021
(86) PCT No.: PCT/US2021/041454

§ 371 Date: Dec. 29, 2022

(30) Foreign Application Priority Data
Jul. 15, 2020 (IN) 202031030200
Feb. 26, 2021 (IN) 202131008257

(51) Int. Cl. H01L 21/677; H01L 21/687; C23C 16/46; C23C 16/28; H01L 21/67

(52) U.S. Cl. CPC H01L 21/67703; H01L 21/68735; C23C 16/463; C23C 16/28; H01L 21/67161

(57) ABSTRACT

In some examples, an exclusion ring locates a substrate on a substrate-support assembly in a processing chamber. An example exclusion ring comprises an inner edge portion to cover an edge of a substrate in the processing chamber and an outer edge portion to support the exclusion ring on the substrate support assembly in the processing chamber. The outer edge portion may include an outer edge of the exclusion ring. A separation zone extending between the inner edge portion and the outer edge of the exclusion ring includes an undercut in an undersurface of the exclusion ring. In some examples, a cooling gas is directed at the exclusion ring while the exclusion ring is located at a station or during an indexing operation performed by the exclusion ring within a processing tool.

### CLAIM OF PRIORITY

This application claims the benefit of priority to Indian Patent Application No. 202031030200, filed on Jul. 15, 2020, and to Indian Patent Application No. 202131008257, filed on Feb. 26, 2021, each of which is incorporated by reference herein in its entirety.

### FIELD

The present disclosure relates generally to an exclusion ring for positioning a substrate, such as a wafer, in substrate processing modules, and more particularly to the use of such an exclusion ring in multi-station processing modules in which a high temperature differential exists between stations. Some examples relate to cooling of an exclusion ring and temperature control.

### BACKGROUND

In some multi-station substrate processing modules, such as a quad station module (QSM), a high temperature differential can exist between stations. Some substrate processing operations in a sequence of operations may occur at very high processing temperatures, while others may not. A significant temperature differential may thus exist between various phases in the sequence. For example, a first station (station 1) in a QSM may operate at a temperature in the range 130-150 degrees Celsius, while stations 2 through 4 of the QSM might operate at a temperature in the range 475-500 degrees Celsius.

An exclusion or carrier ring moves (or indexes) a substrate, such as a silicon wafer, from pedestal to pedestal in each station of the QSM as the substrate undergoes a series of processing operations therein. A conventional carrier ring is typically manufactured from aluminum oxide (Al₂O₃). This material has low thermal conductivity and does not generally transmit heat well along its length. Accordingly, when a conventional exclusion ring transfers a substrate, say, from a low-temperature pedestal in station 1 to a high-temperature pedestal in station 2, the exclusion ring can experience significant thermal shock. The inner edge of the exclusion ring overlying a substrate edge is typically at a much lower temperature compared to the outside edge of the ring where the temperature can be much higher as a result of being in direct contact with the hot pedestal. This inherent and significant thermal imbalance between edges can result in cracking, ring fracture, and premature failure.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### BRIEF SUMMARY

In some examples, an exclusion ring is provided for locating a substrate on a substrate-support assembly in a processing chamber. An example exclusion ring may comprise an inner edge portion to cover an edge of a substrate in the processing chamber; an outer edge portion to support the exclusion ring on the substrate support assembly in the processing chamber, the outer edge portion including an outer edge of the exclusion ring; wherein a separation zone between the inner edge portion and the outer edge of the exclusion ring includes an undercut in an undersurface of the exclusion ring.

In some examples, the undercut at least partially thermally isolates the inner edge portion from the outer edge of the substrate.

In some examples, a wall of the undercut is clear of the substrate support assembly when the substrate is placed on the substrate support assembly.

In some examples, the undercut includes a groove extending at least partially in a circumferential direction around the exclusion ring.

In some examples, the groove is continuous in the circumferential direction around the exclusion ring.

In some examples, the groove is discontinuous in the circumferential direction around the exclusion ring.

In some examples, the undercut is disposed adjacent one or more support formations, the one or more support formations contacting the substrate support assembly when the substrate is placed on the substrate support assembly.

In some examples, the one or more support formations are connected to a thermal bridge defining an upper wall of the undercut.

In some examples, a width of the undercut extends between an inner edge and the outer edge of the exclusion ring.

In some examples, the undercut includes a rectangular cross-section.

In some examples, the undercut includes a non-linear cross-section.

In some examples, the undercut is hollow.

In some examples, wherein the undercut or hollow includes a thermally resistant material or edge gas.

In some examples, the undercut is disposed inside an outer circumference of the exclusion ring.

In some examples, the undercut is disposed at, or includes, an outer circumference of the exclusion ring.

In some examples, the undercut is a first undercut, with the exclusion ring further comprising at least one ear for manipulating the exclusion ring in use, a portion of the at least one ear including a second undercut in an undersurface of the at least one ear.

In some examples, the exclusion ring further comprises one or more gas exit ports.

### BRIEF DESCRIPTION OF THE SEVERAL VIEWS OF THE DRAWINGS

Some embodiments are illustrated by way of example and not limitation in the views of the accompanying drawing:

FIGS. 1-5 show schematic views of substrate processing tools, according to some example embodiments.

FIG. 6 shows a schematic diagram of an example processing chamber within which examples of the present disclosure may be employed.

FIG. 7 shows a pictorial view of an open QSM, according to an example embodiment.

FIGS. SA-8B show comparative sectional and pictorial underside views of a conventional and present embodiment of an exclusion ring, according to example embodiments.

FIGS. 9A-9C and FIGS. 10A-10C show pictorial underside views of various exclusion rings, according to some examples.

FIG. 11 illustrates stress test sites, in accordance with one embodiment.

FIG. 12 is a block diagram illustrating an example of a system controller upon which one or more example embodiments may be implemented or controlled.

FIGS. 13-16 depict aspects of a method of cooling an exclusion ring, according to example embodiments.

FIG. 17 is a flow chart depicting example operations in a method of cooling an exclusion ring in a multi-station substrate processing tool.

### DETAILED DESCRIPTION

The description that follows includes systems, methods, techniques, instruction sequences, and computing machine program products that embody illustrative embodiments of the present disclosure. In the following description, for purposes of explanation, numerous specific details are set forth in order to provide a thorough understanding of example embodiments. It will be evident, however, to one skilled in the art that the present disclosure may be practiced without these specific details.

A portion of the disclosure of this patent document may contain material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to any data as described below and in the drawings that form a part of this document: Copyright Lam Research Corporation, 2020, All Rights Reserved.

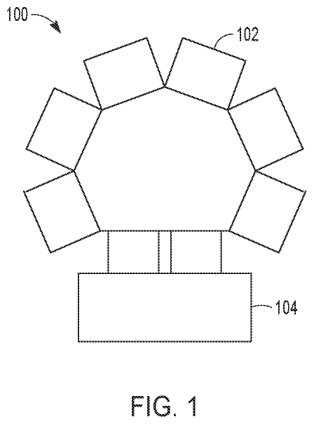

Referring now to FIG. 1, a top-down view of an example substrate processing tool 100 is shown. The substrate processing tool 100 includes a plurality of process modules 102. In some examples, each of the process modules 102 may be configured to perform one or more respective processes on a substrate, Substrates to be processed are loaded into the substrate processing tool 100 via ports of a loading station of an EFEM 104 (equipment front end module) and then transferred into one or more of the process modules 102. For example, a substrate may be loaded into each of the process modules 102 in succession.

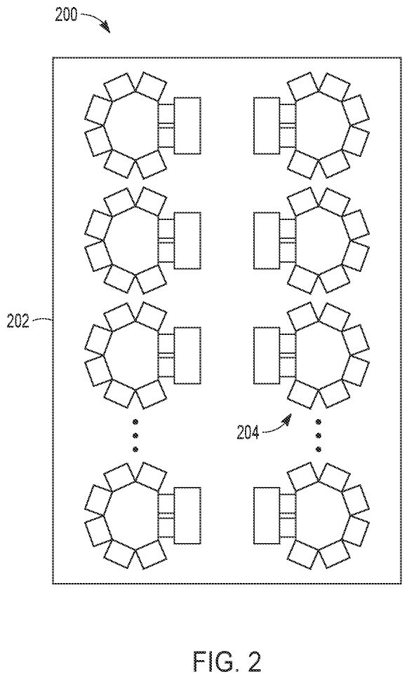

Referring now to FIG. 2, an example arrangement 200 of a fabrication room 202 including a plurality of substrate processing tools 204 is shown.

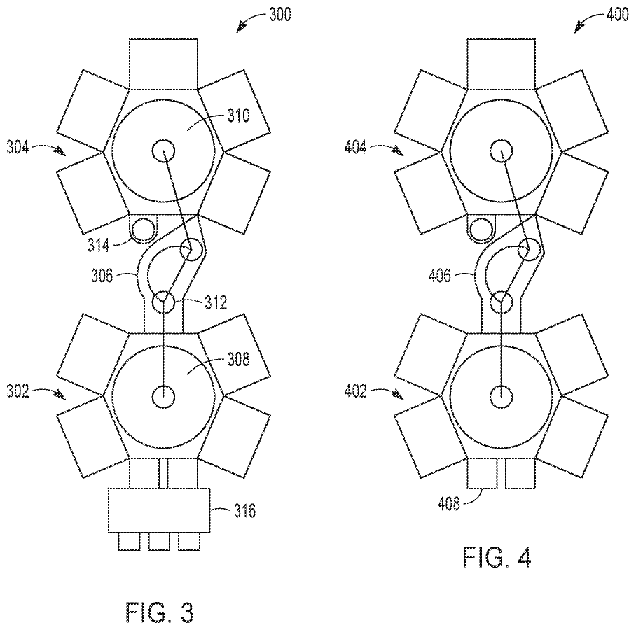

FIG. 3 shows a first example configuration 300 including a first substrate processing tool 302 and a second substrate processing tool 304. The first substrate processing tool 302 and the second substrate processing tool 304 are arranged sequentially and are connected by a transfer stage 306, which is under vacuum. As shown, the transfer stage 306 includes a pivoting transfer mechanism configured to transfer substrates between a VTM 308 (vacuum transfer module) of the first substrate processing tool 302 and a VTM 310 of the second substrate processing tool 304. However, in other examples, the transfer stage 306 may include other suitable transfer mechanisms, such as a linear transfer mechanism.

In some examples, a first robot (not shown) of the VTM 308 may place a substrate on a support 312 arranged in a first position, the support 312 is pivoted to a second position, and a second robot (not shown) of the VTM 310 retrieves the substrate from the support 312 in the second position. In some examples, the second substrate processing tool 304 may include a storage buffer 314 configured to store one or more substrates between processing stages. The transfer mechanism may also be stacked to provide two or more transfer systems between the first substrate processing tool 302 and second substrate processing tool 304. Transfer stage 306 may also have multiple slots to transport or buffer multiple substrates at one time. In the example configuration 300, the first substrate processing tool 302 and the second first substrate processing tool 302 are configured to share a single EFEM 316,

FIG. 4 shows a second example configuration 400 including a first substrate processing tool 402 and a second substrate processing tool 404 arranged sequentially and connected by a transfer stage 406. The example configuration 400 is similar to the example configuration 300 of FIG. 3 except that in the example configuration 400, the EFEM is eliminated. Accordingly, substrates may be loaded into the first substrate processing tool 402 directly via airlock loading stations 408 (e.g., using a storage or transport carrier such as a vacuum wafer carrier, front opening unified pod (FOUP), an atmospheric (ATM) robot, etc., or other suitable mechanisms).

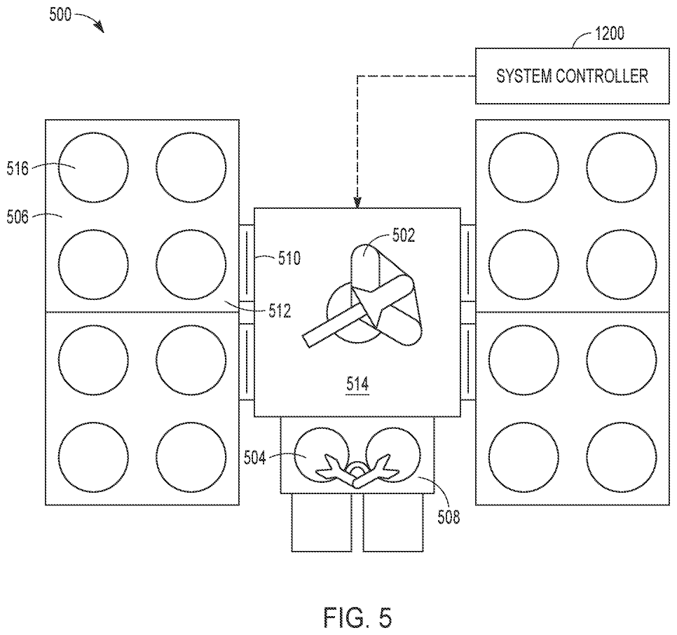

In some examples, the apparatus, systems, and methods of the present disclosure may be applied to QSMs. For instance, as shown in FIG. 5, a substrate processing tool 500 includes four QSMs 506. Each of the QSMs 506 includes four stations 516 (hence quad station module). The substrate processing tool 500 includes a transfer robot 502 and a transfer robot 504, referred to collectively as transfer robots 502/504. The substrate processing tool 500 is shown without mechanical indexers for example purposes. In other examples, respective QSMs 506 of the substrate processing tool 500 may include mechanical indexers to transfer substrates (for example, wafers) from station to station in a given QSM 506. An indexer may include a carrier or exclusion ring described in more detail below. Substrate processing temperatures at each of the stations 516 may vary widely and present a significant challenge to the longevity of certain components, such as the exclusion ring.

A VTM 514 and an EFEM 508 may each include one of the transfer robots 502/504. The transfer robots 502/504 may have the same or different configurations. In some examples, the transfer robot 502 is shown having two arms, with each having two vertically stacked end effectors. The transfer robot 504 of the VTM 514 selectively transfers substrates to and from the EFEM 508 and between the QSMs 506. The transfer robot 504 of the EFEM 508 transfers substrates into and out of the EFEM 508. In some examples, the transfer robot 504 may have two arms, with each arm having a single end effector or two vertically stacked end effectors. A system controller 1200 may control various operations of the illustrated substrate processing tool 500 and its components including, but not limited to, operation of the robots 502/504, rotation of the respective indexers of the QSMs 506, and so forth.

The VTM 514 is configured to interface with, for example, all four of the QSMs 506, with each having a single load station accessible via a respective slot 510. In this example, the sides 512 of the VTM 514 are not angled (i.e., the sides 512 are substantially straight or planar). In this manner, two of the QSMs 506, each having a single load station, may be coupled to each of the sides 512 of the VTM 514. Accordingly, the EFEM 508 may be arranged at least partially between two of the QSMs 506 to reduce a footprint of the substrate processing tool 500.

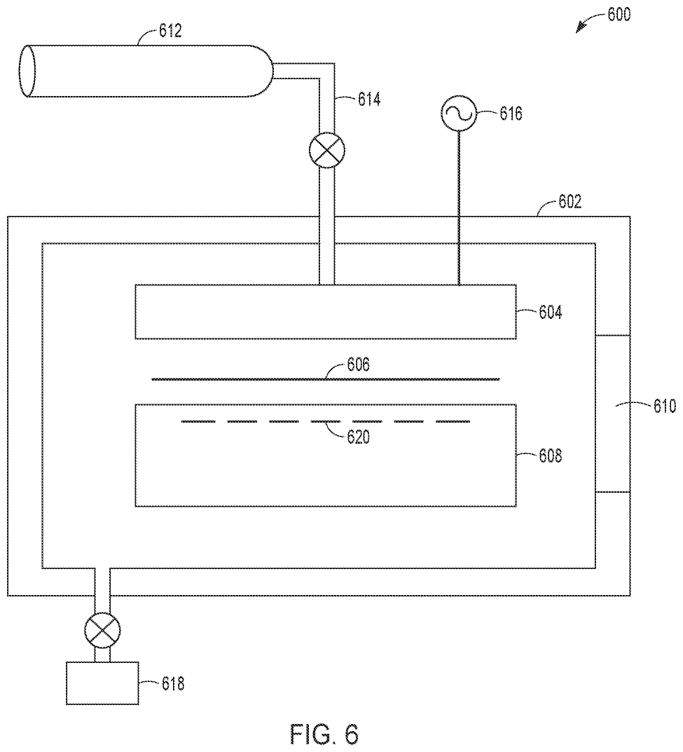

With reference now to FIG. 6, an example arrangement 600 of a plasma-based processing chamber at each of the stations 516 is shown. The present subject matter may be used in a variety of semiconductor manufacturing and substrate processing operations, but in the illustrated example, the plasma-based processing chamber is described in the context of plasma-enhanced or radical-enhanced Chemical Vapor Deposition (C-VD) or Atomic Layer Deposition (ALD) operations. The skilled artisan will recognize that other types of ALD processing techniques are known (e.g., thermal-based ALD operations) and may incorporate a non-plasma-based processing chamber. An ALD tool is a specialized type of CVD processing system in which ALD reactions occur between two or more chemical species. The two or more chemical species are referred to as precursor gases and are used to form a thin film deposition of a material on a substrate, such as a silicon wafer as used in the semiconductor industry. The precursor gases are sequentially introduced into an ALD processing chamber and react with a surface of the substrate to form a deposition layer. Generally, the substrate repeatedly interacts with the precursors to slowly deposit an increasingly thick layer of one or more material films on the substrate. In certain applications, multiple precursor gases may be used to form various types of film or films during a substrate manufacturing process.

FIG. 6 is shown to include a plasma-based processing chamber 602. In which a showerhead 604 (which may be a showerhead electrode) and a substrate-support assembly 608 or pedestal are disposed. Typically, the substrate-support assembly 608 provides a substantially-isothermal surface and may serve as both a heating element and a heat sink for a substrate 606. The substrate-support assembly 608 may comprise an Electrostatic Chuck (ESC) in which heating elements are included to aid in processing the substrate 606, as described above. The substrate 606 may include a wafer comprising, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz, sapphire, semi-crystalline polymers, or other non-metallic and non-semiconductor materials.

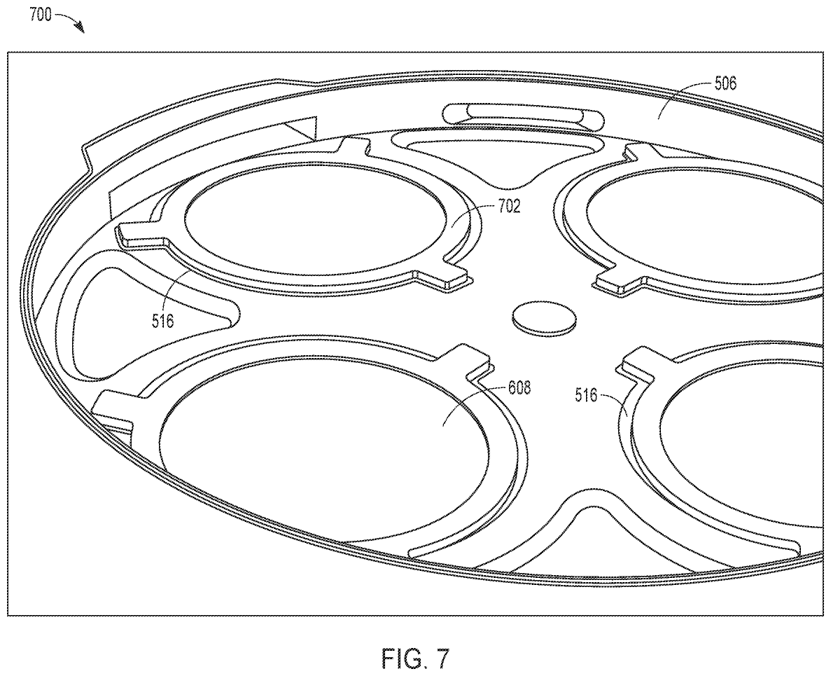

In operation, the substrate 606 is loaded through a loading port 610 onto the substrate-support assembly 608. An exclusion ring 702 (FIG. 7) or 802 (FIG. 8) may load the substrate onto the substrate-support assembly 608. Other loading arrangements are possible. A gas line 614 can supply one or more process gases (e.g., precursor gases) to the showerhead 604. In turn, the showerhead 604 delivers the one or more process gases into the plasma-based processing chamber 602. A gas source 612 (e.g., one or more precursor gas ampules) to supply the one or more process gases is coupled to the gas line 614. In some examples, an RF (radio frequency) power source 616 is coupled to the showerhead 604. In other examples, a power source is coupled to the substrate-support assembly 608 or ESC.

Prior to entry into the showerhead 604 and downstream of the gas line 614, a point-of-use (POU) and manifold combination (not shown) controls entry of the one or more process gases into the plasma-based processing chamber 602. In the case of a plasma-based processing chamber 602 used to deposit thin films in a plasma-enhanced ALD operation, precursor gases may be mixed in the showerhead 604.

In operation, the plasma-based processing chamber 602 is evacuated by a vacuum pump 618. RF power is capacitively coupled between the showerhead 604 and a lower electrode 620 contained within the substrate-support assembly 608. The substrate-support assembly 608 is typically supplied with two or more RF frequencies. For example, in various embodiments, the RF frequencies may be selected from at least one frequency at about 1 MHz, 2 MHz, 13.56 MHz, 27 MHz, 60 MHz, and other frequencies as desired. A coil designed to block or partially block a particular RF frequency can be designed as needed. Therefore, particular frequencies discussed herein are provided merely for ease in understanding. The RF power is used to energize the one or more process gases into a plasma in the space between the substrate 606 and the showerhead 604. The plasma can assist in depositing various layers (not shown) on the substrate 606. In other applications, the plasma can be used to etch device features into the various layers on the substrate 606. RF power is coupled through at least the substrate-support assembly 608. The substrate-support assembly 608 may have heaters (not shown in FIG. 6) incorporated therein. The detailed design of the plasma-based processing chamber 602 may vary.

FIG. 7 is a pictorial view 700 of an open QSM 506. Four stations 516 of the QSM 506 may be seen. Each of the stations 516 is associated with a carrier or exclusion ring 702. An exclusion ring 702 locates a substrate on a substrate-support assembly at each station 516. In one aspect, the exclusion ring 702 carries or “indexes” a substrate to or from a pedestal for processing. In another aspect, an exclusion ring 702 “excludes” or protects an edge of the substrate it is carrying from deposition chemistries and processing. This excluded region is known as an edge exclusion zone.

FIG. 8A shows sectional and pictorial underside views 800 of a conventional exclusion ring 802. FIG. 8B shows sectional and underside views of an example exclusion ring 702 of the present disclosure. With reference to either figure, an exclusion ring 702 or 802 can be placed on the periphery of a substrate-support assembly 608 such that an inner edge zone 804 of the exclusion ring overlies an outer edge exclusion zone of a substrate 606. A gap 806 receives an outer edge of the substrate 606. The substrate-support assembly 608 may include an edge gas groove 808. The edge gas groove 808 emits gas to isolate the edge exclusion zone.

As discussed above, in some multi-station substrate processing modules, such as a QSM, a high temperature differential may exist between processing stations of the module. Some substrate processing operations performed at successive stations in the module may occur at varying temperatures. A significant temperature differential may exist between stations in a given sequence of operations. For example, a first station (station 1) in a QSM may operate at a temperature in the range 130-150 degrees Celsius, while stations 2 through 4 of the QSM might operate at a temperature in the range 475-500 degrees Celsius.

The conventional exclusion ring 802 of FIG. 8A is typically manufactured from aluminum oxide (Al₂O₃). This material has low thermal conductivity and does not generally transmit heat well along its length or breadth. Accordingly, when a conventional exclusion ring 802 transfers a substrate, say, from a low-temperature pedestal in station 1 to a high-temperature pedestal in station 2, the exclusion ring 802 can experience significant thermal shock. The inner edge of the exclusion ring 802 overlying a substrate edge is typically at a significantly lower temperature compared to the outside edge of the ring 802 where the ring temperature can be significantly higher as a result of being in direct contact with a hot substrate-support assembly 608. This inherent and significant thermal imbalance between the edges of the exclusion ring 802 can create significant stress build-up resulting in cracking, ring fracture, and premature failure. In seeking to address these challenges, example embodiments of an exclusion ring 702 (for example, FIG. 8B) of the present disclosure have an enhanced configuration and geometry.

With reference again to FIG. 8B, an example exclusion ring 702 of the present disclosure includes an inner edge zone 804 which overlies an edge of a substrate, for example substrate 606, in a processing chamber, such as processing chamber 602. The exclusion ring 702 further includes an outer edge zone 810 to support the exclusion ring on a substrate support assembly (for example, substrate-support assembly 608 in processing chamber 602). The outer edge zone 810 may include an outer edge 826 of the exclusion ring 702. A separation zone 812 between the inner edge zone 804 and the outer edge 826 of the exclusion ring 702 includes a groove, slot, or undercut 814 formed in an undersurface of the exclusion ring 702, The undercut 814 may be integrally formed with the exclusion ring 702 or, in some examples, formed by a machining out of some material of the exclusion ring 702.

In some examples, the undercut 814 is configured so that the interior walls of the undercut 814 do not make contact with the substrate-support assembly 608. An upper wall 816 of the undercut 814 (or bottom of the groove 814) is held clear of the substrate-support assembly 608 and removed from direct thermal contact therewith. In the illustrated example, the undercut 814 is hollow and creates an air gap. The air gap of the undercut 814 provides a thermal barrier between the inner edge zone 804 and outer edge zone 810 of the exclusion ring 702. In some examples, the internal volume or cavity of the undercut 814 includes an edge gas. In some examples, the internal volume or cavity of the undercut 814 is fully or partially filled with a solid or semi-solid material that exhibits a thermal resistance higher than air. Other thermal barriers are possible.

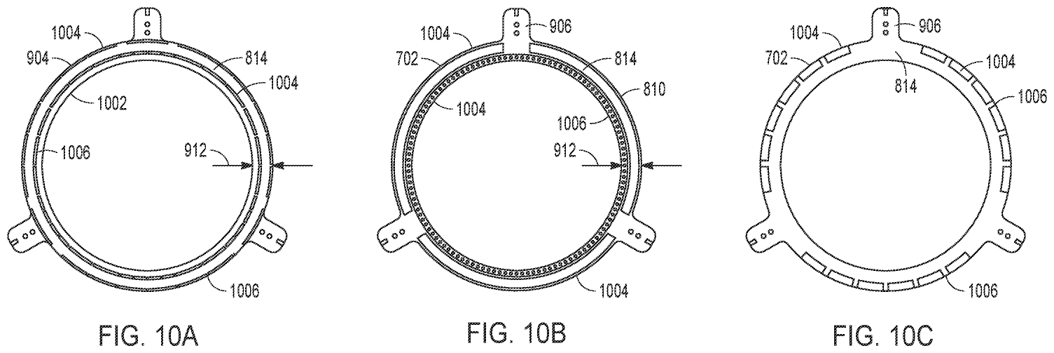

As shown in FIG. 8B, in some examples the undercut 814 includes or is constituted by a circular groove 814 that extends at least partially in a circumferential direction around the exclusion ring 702. The groove 814 may be discontinuous (as shown) to leave gaps 824. The gaps may serve as edge gas exit ports discussed further below with reference to FIG. 10.

In some examples, the undercut 814 is defined, or bordered by, at least two support formations. In some examples, the support formations include spaced feet 820, which contact the substrate-support assembly 608 (or pedestal) when the substrate 606 is placed thereon by the exclusion ring 702. In the lower view of FIG. 8B, the feet 820 are generally circular in plan view and follow the circumferential contour of the undercut 814, The feet 820 are disposed in the outer edge zone 810 of the exclusion ring 702. The radially inner foot 820 is continuous around the exclusion ring 702. The radially outer foot 820 may be discontinuous around its circumference. The opposite, or other, configurations are possible. In some examples, the feet 820 define side walls for the undercut 814, as shown in FIG. 8B for example. The upper wall 816 of the undercut (groove) 814 and the feet 820 define an internal volume or cavity of the undercut 814.

In some examples, the feet 820 are joined by a thermal bridge 822. In the example illustrated in FIG. 8B, the thermal bridge 822 includes or defines the upper wall 816 of the undercut 814. In the illustrated exclusion ring 702 of that view, the undercut 814 includes a rectangular cross-section. The undercut 814 may include this cross-sectional shape throughout its circular length. In other examples, the undercut 814 includes a non-linear or non-rectangular cross-section, with the undercut 814 uniformly shaped along its length accordingly. In some examples, the undercut 814 includes a combination of cross-sections which may vary around the circumferential direction of the exclusion ring 702.

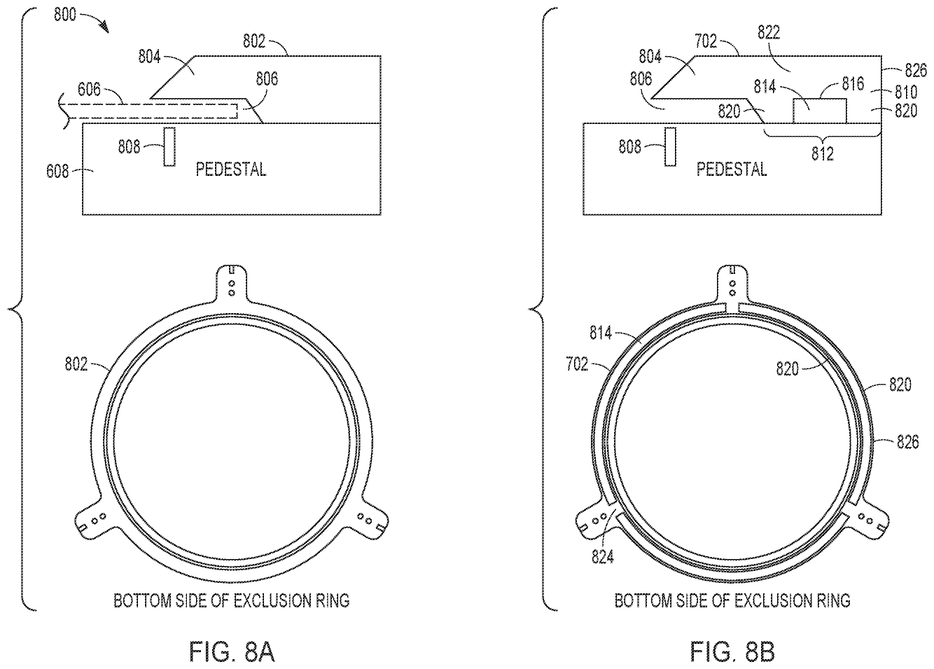

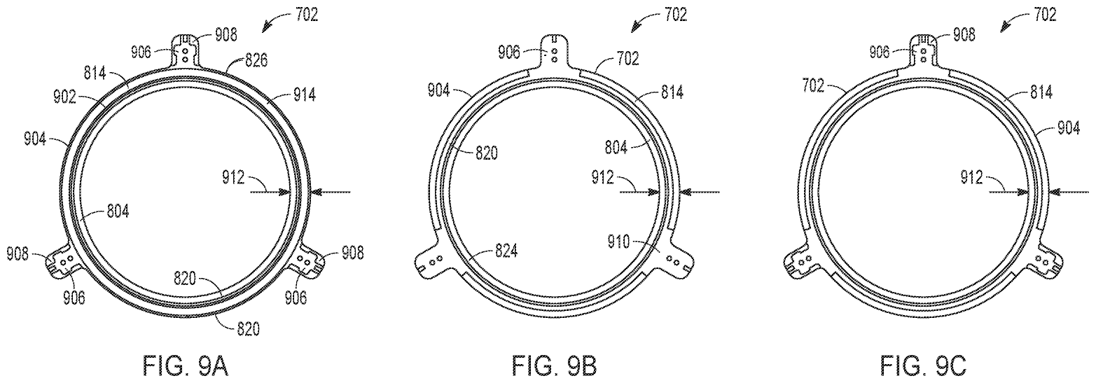

Various examples of an exclusion ring 702 are illustrated in FIGS. 9A-9C and FIGS. 10A-10C. These examples are configured to reduce the creation of significant temperature gradients arising within or across a radial width 912 of the exclusion ring 702. As illustrated, in some examples (for example. FIG. 9A) the undercut 814 is continuous in the circumferential direction around the exclusion ring 702. The undercut 814 is disposed inside an outer edge 904 of the exclusion ring. The example configuration of the undercut 814 in conjunction with spaced feet 820 positioned on either side of the undercut 814 causes the exclusion ring 702 to heat up approximately equally in two respective location or zones: first, in a central zone 914 of the ring 702 disposed at the location of the inner foot 820 in the illustrated example and, second, at its outer edge 904 at the location of the outer foot 820. The feet 820 receive heat from the substrate-support assembly 608 while other portions of the exclusion ring 702 are held clear of this heat source. This even or equal temperature rise serves to reduce thermal gradients of the type discussed above which can lead to cracking and premature ring failure.

In the illustrated example of FIG. 9A, the exclusion ring 702 includes a plurality of fingers or ears 906. In this case, three ears 906 are provided. The ears 906 can be used to manipulate the exclusion ring 702. In this example, the undercut 814 (here, the example continuous groove 902) defines a first undercut while a portion of the ears 906 includes a second undercut 908 formed in an undersurface of the at least one ear. In some examples, the second undercut 908 is provided along outer edges of the ears 906, as shown. Other arrangements are possible.

In the example of FIG. 9B, the configuration of the undercut 814 and location of a single foot 820 adjacent thereto causes the exclusion ring 702 to heat up faster in the center of its radial width 912 than at its outer edge 904 or in the outer edge zone 810. The contact of the single foot 820 with the pedestal receives heat and the temperature rises accordingly, Other zones of the exclusion ring 702 are held clear of that heat source and their temperatures do not rise as fast. In this illustrated example, the first undercut 814 is discontinuous and at gaps 824 does not extend into a zone 910 adjacent each of the ears 906, The ears 906 do not include a second undercut.

In the example exclusion ring 702 of FIG. 9C, the undercut 814 is at an outer edge 904 of the exclusion ring 702. The ears 906 include a second undercut 908. The second undercut 908 reduces thermal contact between the exclusion ring 702 and the substrate-support assembly 608 at the outer edges of the ears 906 and the center of the radial width 912 of the exclusion ring 702.

With reference to FIGS. 10A-10C, in the example embodiment of FIG. 10A, the undercut 814 is radially broader relative to the examples discussed above and extends fully across the radial width 912 width of the exclusion ring 702. In this example, the undercut 814 extends between the inner edge 1002 and outer edge 904 of the exclusion ring 702. In some examples, the undercut 814 is supported away from the substrate-support assembly 608 at least in part by one or more circular feet 1004 defining at least one interior wall of the recess. As shown, in some examples, one of the feet 1004 is located at approximately the middle of the radial width 912 of the exclusion ring 702. Another foot 1004 is at the outer edge 904. Other feet locations are possible.

Further configurations of the exclusion ring 702 are shown in FIG. 10B and FIG. 10C. The example undercut configuration illustrated in FIG. 10B is configured to allow the center of the radial width 912 and the outer edge zone 810 to heat up a similar rate to reduce the creation of significant thermal gradients between these two areas. The design includes a full-width undercut 814 and is configured to reduce heat transfer to the outer edge 904 or outer edge zone 810, accordingly. The example undercut configuration illustrated in FIG. 10C is further configured to allow a radial exit of edge gas flow. An example gas exit configuration includes radial slots or ports 1006 provided through a foot 1004 in the outer edge zone 810 of the exclusion ring 702. Further example gas exit ports 1006 are shown in FIGS. 10A-10B.

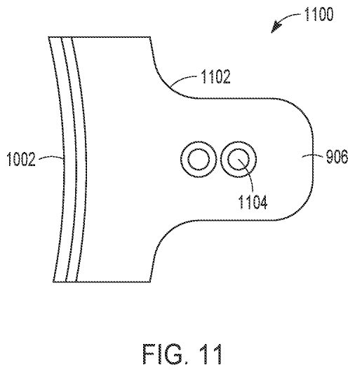

With reference to FIG. 11, an example exclusion ring 702 was stress tested to determine the ability of this example to reduce stress build-up during thermal cycling. Stress measurements were taken at stress test sites 1100 including at an inner edge 1002 of the exclusion ring 702, an ear radius 1102, and an ear hole 1104. When compared to a conventional exclusion ring 802, the exclusion ring 702 configuration provided stress reductions at one or more of the stress test sites 1100 in the range of approximately 40-50% for thermal cycles ranging between 150-475 degrees Centigrade. An assessed failure rate of the exclusion ring 702 was reduced to 0.005%. After being subjected to over one thousand thermal cycles, no ring failure or cracking was apparent.

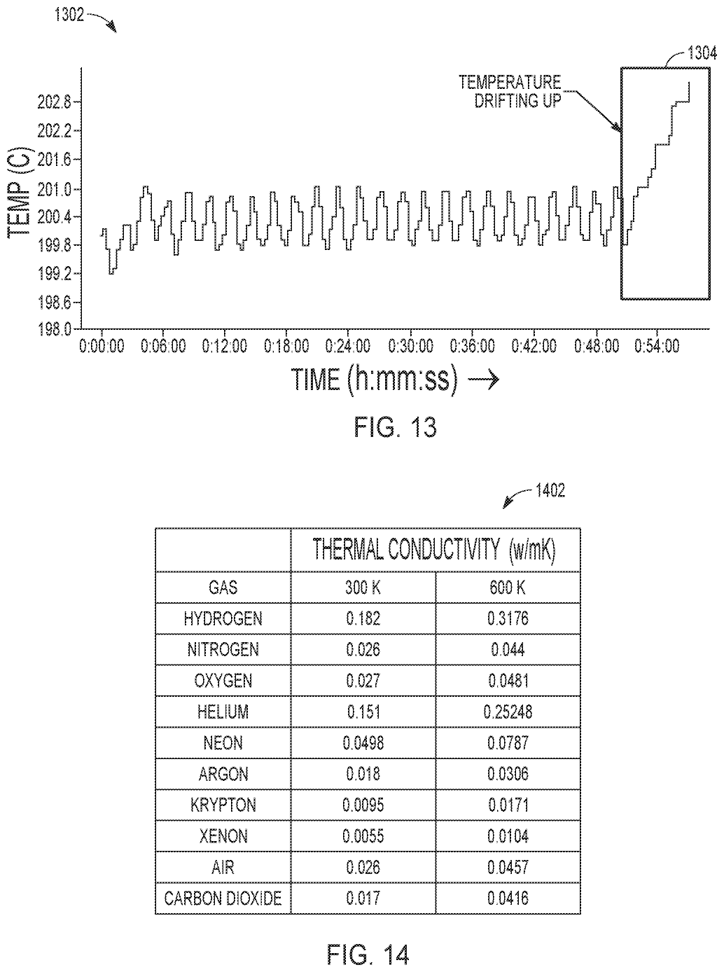

Some example exclusion rings may be employed in temperature control applications or in mitigating heat build-up. With reference to FIG. 13, the graph 1302 plots temperature (y axis) against time (x axis) for a first station 516 (station 1) in a QSM 506 (FIG. 5). In some examples, the first station 516 operates at a temperature of approximately 200° C. Station 1 may experience a significant upward temperature drift, as shown, for example, by zone 1304 in the graph 1302. This temperature increase can significantly impact control systems and adversely affect substrate processing conditions, particularly at station 1. In extreme cases, station 1 becomes unable to control its own temperature and a runaway situation may occur. It has been found that a root cause of this phenomenon is the transfer of a hot exclusion ring 702 from a higher, hotter upstream station, for example a station 2, 3, or especially a station 4 operating at 430° C., for example.

In order to address this phenomenon, some present examples include a method for cooling an exclusion ring, with the method including a cooling operation comprising supplying or directing a ring cooling gas at an exclusion ring in a multi-station tool, such as a QSM. A ring cooling gas may include, in whole or in part, one or more of the ring cooling gases listed in Table 1402 in FIG. 14.

The ring cooling gases each have a respective thermal conductivity, as shown, at temperatures of 300K and 600K, respectively. The units of the thermal conductivity values shown in Table 1402 are watts per meter Kelvin (w/mK). The thermal conductivity value of a ring cooling gas may be selected, in some examples, based on a working temperature of a QSM station, for example a station 1 operating in a range in the order of 100″ and 250″C. Thus, thermal conductivity values at 300K and 600K may be applicable for a process at that station. A ring cooling gas may have a thermal conductivity in a range that includes and extends between its respective thermal conductivity values for 300K and 600K, as shown in Table 1402.

In some examples, a ring cooling gas may be a pure or a mixed gas. The pure or mixed gas may have a thermal conductivity greater than or equal to 0.005 w/mK. In some examples, the thermal conductivity of a ring cooling gas is selected independently of any specific constituent or constituents of the ring cooling gas. In some examples, the selection or creation of a ring cooling gas is based purely on a desired value of thermal conductivity and is agnostic to the cooling gas contents.

In some examples, a thermal conductivity of a ring cooling gas is dependent on pressure. Pressure (P) is typically measured at atmospheric pressure, namely approximately 100 kPa, or 1 bar. In some examples, a difference in thermal conductivity due to pressure difference between P=0 and P=100 kPa is less than 1%.

In some examples, gas temperature may be important because phonon or thermal transfer deltas are dependent on a temperature gradient. Generally, a ring cooling effect (heat transfer) is relatively high for a relatively large temperature difference between a ring cooling gas and an exclusion ring that the gas is seeking to cool. In some examples, a ring cooling gas temperature is in the range between 20K and an operating temperature of a station (for example, a station in a QSM). In some examples, the ring cooling gas is supplied or directed at an exclusion ring in this temperature range.

The exclusion ring may be cooled by a ring cooling gas during a transfer between stations, or at a station, in a multi-station tool, such as a QSM. The transfer of an exclusion ring may include being seated at a first station, being unseated from the first station, and being seated at a second station.

In some examples, an exclusion ring is unseated by lifting pins. The unseating may allow the exclusion ring to commence carrying and indexing a substrate, such as a wafer, from station to station in a QSM. A substrate or exclusion ring may experience a significant degree of thermal shock when moving from a hotter to a colder station and vice versa. In some examples, a pre-cooling operation for an exclusion ring is provided in the period between being seated at a first station and being reseated at a subsequent station.

In some examples, the pre-cooling of an exclusion ring is performed while the exclusion ring is supported by lift pins. In some examples, the exclusion ring (or a substrate supported by it) is pre-cooled while supported at a midpoint or intermediate position of the lift pins. The exclusion ring or substrate may be in motion or stationary while being cooled by the ring cooling gas. In some examples, the exclusion ring or substrate is cooled while the substrate or exclusion ring is being lifted by the pins (i.e., is in motion). In some examples, the lint pins are held at an end or intermediate position of their travel so as to provide a (temporarily) fixed cooling location for an exclusion ring or a substrate supported by the ring. The ring cooling gas may be supplied to a process chamber or directed at the substrate or exclusion ring while the substrate or exclusion ring is generally supported by the lift pins, or at any of the specific cooling locations or arrangements discussed above. The example lift pin methods described above may be applied to lift pins unseating an exclusion ring from a first station (i.e., an ascending ring), and also to lift pins that operate to lower or support an exclusion ring during a descent of the ring onto a second station.

Some examples of ring cooling methods include selection of a cooling gas flow direction and/or a gas flow rate. A ring cooling gas maybe supplied to a processing chamber, for example, the processing chamber 602 (FIG. 6), or directed at an exclusion ring or substrate therein by a showerhead, for example, from above the exclusion ring by the showerhead 604 of FIG. 6. In this example, the ring cooling gas flows downwardly during ring cooling. In some examples, the ring cooling gas is supplied to a processing chamber, or directed at an exclusion ring or substrate therein by a substrate-support assembly, for example, from below the exclusion ring by a substrate-support assembly or pedestal 608 (FIG. 6). In this example, the ring cooling gas flows upwardly during ring cooling. In some examples, a ring cooling gas is supplied to a processing chamber, or directed at an exclusion ring or substrate therein, from several different directions, for example, by a showerhead and a substrate-support assembly (i.e., from above and below). In some examples, a chilled ring cooling gas is supplied, the chilled ring cooling gas having a gas temperature lower than a substrate processing temperature. To that end, a gas chiller, insulators, and gas temperature monitoring system may be supplied and included in a substrate processing tool or chamber,

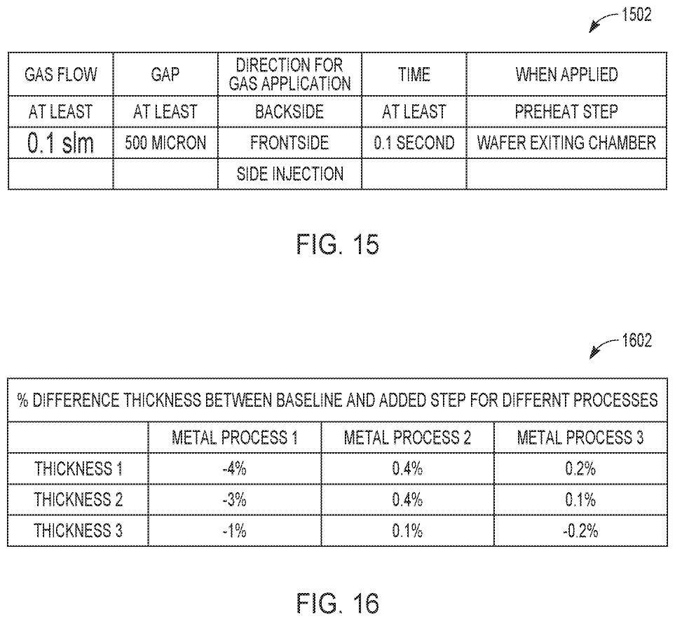

FIG. 15 includes a Table 1502 of process parameters in a method of cooling an exclusion ring. The parameters include a gas flow, a pedestal gap, a direction of gas application, a gas application time, and when the gas is applied. The Table 1502 indicates example values for these example parameters. In some examples, a ring cooling gas is supplied to a processing chamber or directed at an exclusion ring at a gas flow rate in the range 0.1-100 standard cubic centimeters per minute (sccm).

Some examples of ring cooling methods address challenges that can arise in pedestal heater idling. Pedestal heater idling relates to a cycling through one or more heating and cooling steps during substrate processing at a station, for example, a station in a QSM. As mentioned above, a pedestal 608 may have heating elements inside it. These elements are heated when the pedestal temperature drops to maintain an even substrate processing temperature. In some examples, heat may be applied (or not applied, as the case may be) during indexing of a wafer from station to station. For example, pedestal heat may be withheld when a hot wafer arrives from a hotter upstream station, or pedestal heat may be applied if a wafer is received from a cooler station.

A proportion or ratio of time that pedestal heaters are turned on or off (idling) is known as a pedestal idling value, or PID. It is not ideal to have a high PID as this can imply large changes in temperature. Ideally, a PID should be zero. Present examples of the exclusion ring, and methods of cooling an exclusion ring, have reduced PID values in the range 10-90%.

Some examples address issues that can arise in wafer cycling frequency. Typically, each substrate process has an execution time, which is related to indexing frequency, and/or a particle recipe (for example, an execution time of 90 seconds per execution, with a new wafer arriving at a station every 90 seconds). During a long process, an indexing time may be 10 minutes, especially if a cooling period is factored into that time. In boosting the cooling of exclusion rings and substrates, example cooling methods described herein can shorten indexing times. Alternatively, if a desired indexing time is sought to be maintained (e.g., 90 seconds), present methods enable mitigation of added heat and management of upward temperature drift. This mitigation and management allows the retention of shorter index times. The use of a ring cooling gas as described herein can address higher station-to-station temperature differentials and accommodate heat build-up associated with shorter index times.

If needed, substrates or wafers may be held at a cooling location and soaked in a given cooling gas to meet process requirements as appropriate. Examples of the ring cooling methods described herein interfere very minimally with substrate or wafer production. They have very little, if any, process impact. FIG. 16 includes a Table 1602 showing small percentage differences in metal film thicknesses created by conventional (baseline) substrate processes as compared to corresponding metal film thicknesses created by a substrate process which included a cooling method of the present disclosure (i.e., an added step). As shown, comparative “baseline” and “added step” results were obtained in relation to three different film thicknesses created by three different metal processes.

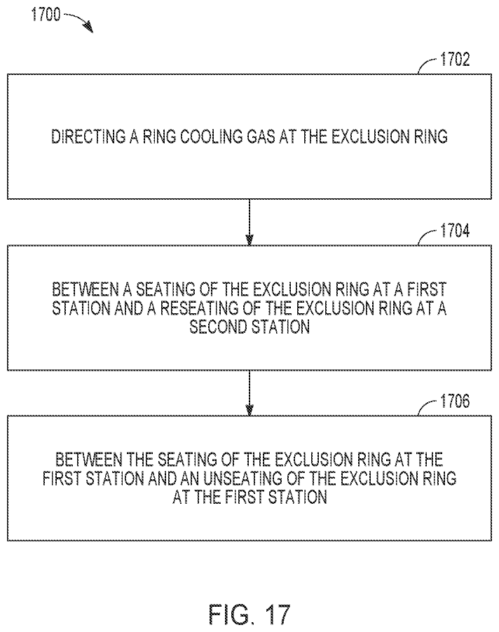

FIG. 17 is a flow chart depicting example operations in a method 1700 of cooling an exclusion ring in a multi-station substrate processing tool. The method 1700 may comprise: at operation 1702, directing a ring cooling gas at the exclusion ring while the exclusion ring is located at a station or during an indexing operation performed by the exclusion ring within the processing tool.

In some examples, at 1704, a duration of the indexing operation extends inclusively between a seating of the exclusion ring at a first station and a reseating of the exclusion ring at a second station.

In some examples, at 1706, the duration extends inclusively between the seating of the exclusion ring at the first station and an unseating of the exclusion ring at the first station.

In some examples, the exclusion ring is unseated by lift pins.

In some examples, the method 1700 further comprises directing the ring cooling gas at the exclusion ring while the exclusion ring is supported by the lift pins.

In some examples, the method 1700 further comprises directing the ring cooling gas at the exclusion ring while the exclusion ring is supported at an intermediate position of the lift pins.

In some examples, the ring cooling gas includes at least one of a group of gases comprising: hydrogen, nitrogen, oxygen, helium, neon, argon, krypton, and xenon.

In some examples, the ring cooling gas includes hydrogen.

In some examples, the ring cooling gas has a thermal conductivity equal to or greater than 0.005 watts per meter Kelvin (w/mK).

In some examples, the ring cooling gas is a chilled ring cooling gas, the chilled ring cooling gas having a gas temperature lower than a substrate processing temperature.

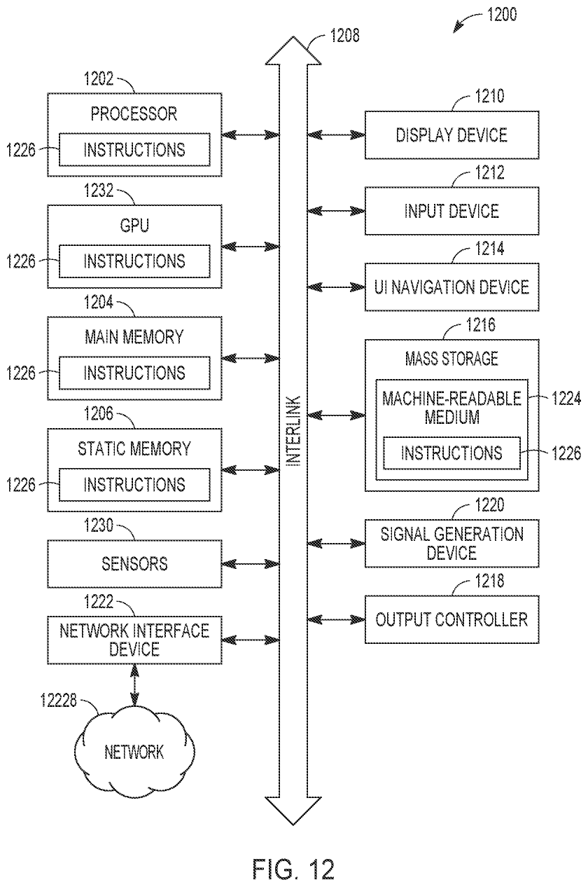

FIG. 12 is a block diagram illustrating an example of a system controller 1200 by which one or more example embodiments described herein may be implemented or controlled. In alternative embodiments, the system controller 1200 may operate as a standalone device or may be connected (e.g., networked) to other machines. In a networked deployment, the system controller 1200 may operate in the capacity of a server machine, a client machine, or both in server-client network environments. In an example, the system controller 1200 may act as a peer machine in a peer-to-peer (P2P) (or other distributed) network environment. Further, while only a single system controller 1200 is illustrated, the term “machine” (controller) shall also be taken to include any collection of machines (controllers) that individually or jointly execute a set (or multiple sets) of instructions to perform any one or more of the methodologies discussed herein, such as via cloud computing, software as a service (SaaS), or other computer cluster configurations. In some examples, and referring to FIG. 12, a non-transitory machine-readable medium includes instructions 1226 that, when read by a system controller 1200, cause the controller to control operations in methods comprising at least the non-limiting example operations described herein.

Examples, as described herein, may include, or may operate by logic, a number of components, or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a Computer-Readable Medium physically modified (e.g., magnetically, electrically, by moveable placement of invariant massed particles, etc.) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the Computer-Readable Medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) system controller 1200 may include a hardware processor 1202 (e.g., a central processing unit (CPU), a hardware processor core, or any combination thereof), a GPU 1232 (graphics processing unit), a main memory 1204, and a static memory 1206, some or all of which may communicate with each other via an interlink 1208 (e.g., a bus) The system controller 1200 may further include a display device 1210, an alphanumeric input device 1212 (e.g., a keyboard), and a user interface (UI) navigation device 1214 (e.g., a mouse or other user interface). In an example, the display device 1210, alphanumeric input device 1212, and UI navigation device 1214 may be a touch screen display. The system controller 1200 may additionally include a mass storage device 1216 (e.g., drive unit), a signal generation device 1220 (e.g., a speaker), a network interface device 1222, and one or more sensors 1230, such as a Global Positioning System (GPS) sensor, compass, accelerometer, or another sensor. The system controller 1200 may include an outer 1218, such as a serial (e.g., universal serial bus (USB)), parallel, or other wired or wireless (e.g., infrared (IR), near field communication (NFC), etc.) connection to communicate with or control one or more peripheral devices (e.g., a printer, card reader, etc.).

The mass storage device 1216 may include a machine-readable medium 1224 on which is stored one or more sets of data structures or instructions 1226 (e.g., software) embodying or utilized by any one or more of the techniques or functions described herein. The instructions 1226 may as shown also reside, completely or at least partially, within the main memory 1204, within the static memory 1206, within the hardware processor 1202, or within the GPU 1232 during execution thereof by the system controller 1200. In an example, one or any combination of the hardware processor 1202, the GPU 1232, the main memory 1204, the static memory 1206, or the mass storage device 1216 may constitute the machine-readable medium 1224.

While the machine-readable medium 1224 is illustrated as a single medium, the term “machine-readable medium” may include a single medium, or multiple media e.g., a centralized or distributed database, and/or associated caches and servers)) configured to store the one or more instructions 1226.

The term “machine-readable medium” may include any medium that can store, encode, or carry instructions 1226 for execution by the system controller 1200 and that cause the system controller 1200 to perform any one or more of the techniques of the present disclosure, or that can store, encode, or carry data structures used by or associated with such instructions 1226. Non-limiting machine-readable medium examples may include solid-state memories, and optical and magnetic media. In an example, a massed machine-readable medium comprises a machine-readable medium 1224 with a plurality of particles having invariant (e.g., rest) mass. Accordingly, massed machine-readable media are not transitory propagating signals. Specific examples of massed machine-readable media may include non-volatile memory, such as semiconductor memory devices (e.g., electrically programmable read-only memory (EPROM), electrically, erasable programmable read-only memory (EEPROM)) and flash memory devices; magnetic disks, such as internal hard disks and removable disks; magneto-optical disks; and CD-ROM and DVD-ROM disks. The instructions 1226 may further be transmitted or received over a communications network 1228 using a transmission medium via the network interface device 1222.

Although examples have been described with reference to specific example embodiments or methods, it will be evident that various modifications and changes may be made to these embodiments without departing from the broader scope of the embodiments. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This detailed description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

1. An exclusion ring for locating a substrate on a substrate-support assembly in a processing chamber; the exclusion ring comprising:
an inner edge portion to cover an edge of a substrate in the processing chamber;
an outer edge portion to support the exclusion ring on the substrate support assembly in the processing chamber, the outer edge portion including an outer edge of the exclusion ring;
wherein a separation zone between the inner edge portion and the outer edge of the exclusion ring includes an undercut in an undersurface of the exclusion ring.

2. The exclusion ring of claim 1, wherein the undercut at least partially thermally isolates the inner edge portion from the outer edge of the substrate.

3. The exclusion ring of claim 1, wherein a wall of the undercut is clear of the substrate support assembly when the substrate is placed on the substrate support assembly.

4. The exclusion ring of claim 1, wherein the undercut includes a groove extending at least partially in a circumferential direction around the exclusion ring.

5. The exclusion ring of claim 4, wherein the groove is continuous in the circumferential direction around the exclusion ring.

6. The exclusion ring of claim 4, wherein the groove is discontinuous in the circumferential direction around the exclusion ring.

7. The exclusion ring of claim 1, wherein the undercut is disposed adjacent one or more support formations, the one or more support formations contacting the substrate support assembly when the substrate is placed on the substrate support assembly.

8. The exclusion ring of claim 7, wherein the one or more support formations are connected to a thermal bridge defining an upper wall of the undercut.

9. The exclusion ring of claim 1, wherein a width of the undercut extends between an inner edge and the outer edge of the exclusion ring.

10. The exclusion ring of claim 1, wherein the undercut is a first undercut; and
wherein the exclusion ring further comprises at least one ear for manipulating the exclusion ring in use, a portion of the at least one ear including a second undercut in an undersurface of the at least one ear.

11. A method of cooling an exclusion ring in a multi-station substrate processing tool, the method comprising:
directing a ring cooling gas at the exclusion ring while the exclusion ring is located at a station or during an indexing operation performed by the exclusion ring within the substrate processing tool.

12. The method of claim 11, wherein a duration of the indexing operation extends inclusively between a seating of the exclusion ring at a first station and a resenting of the exclusion ring at a second station.

13. The method of claim 12, wherein the duration extends inclusively between the seating of the exclusion ring at the first station and an unseating of the exclusion ring at the first station.

14. The method of claim 11, wherein the exclusion ring is unseated by lift pins.

15. The method of claim 14, further comprising directing the ring cooling gas at the exclusion ring while the exclusion ring is supported by the lift pins.

16. The method of claim 15, further comprising directing the ring cooling gas at the exclusion ring while the exclusion ring is supported at an intermediate position of the lift pins.

17. The method of claim 11, wherein the ring cooling gas comprises at least one of a group of gases comprising: hydrogen, nitrogen, oxygen, helium, neon, argon, krypton, and xenon.

18. An exclusion ring for locating a substrate on a substrate-support assembly in a processing chamber; the exclusion ring comprising:
an inner edge portion to cover an edge of a substrate in the processing chamber:
an outer edge portion to support the exclusion ring on the substrate support assembly in the processing chamber;
wherein a separation zone between the inner edge portion and the outer edge of the exclusion ring includes an undercut in an undersurface of the exclusion ring, wherein the undercut at least partially thermally isolates the inner edge portion from the outer edge of the substrate.

19. The exclusion ring of claim 18, wherein a wall of the undercut is clear of the substrate support assembly when the substrate is placed on the substrate support assembly.

20. The exclusion ring of claim 18, wherein the undercut includes a groove extending at least partially in a circumferential direction around the exclusion ring.
